(19) United States
(12) Patent Application Publication
(10) Pub. No.: US 2019/0096317 A1
(43) Pub. Date: Mar. 28, 2019

(54) DISPLAY PANEL, METHOD FOR DRIVING THE SAME AND DISPLAY APPARATUS

(71) Applicant: BOE TECHNOLOGY GROUP CO., LTD., Beijing (CN)

(72) Inventors: Xiaochuan CHEN, Beijing (CN); Minghua XUAN, Beijing (CN); Pengxia LIANG, Beijing (CN); Can ZHANG, Beijing (CN); Can WANG, Beijing (CN); Ming YANG, Beijing (CN); Han YUE, Beijing (CN)

(73) Assignee: BOE TECHNOLOGY GROUP CO., LTD., Beijing (CN)

(21) Appl. No.: 15/982,094

(22) Filed: May 17, 2018

(30) Foreign Application Priority Data
Sep. 28, 2017 (CN) 201710896934.1

(51) Int. Cl. G09G 3/32; H01L 27/12; H01L 29/08; H01L 29/786

(52) U.S. Cl. CPC G09G 3/32; H01L 29/786; H01L 29/0847; H01L 27/1214

(57) ABSTRACT

The present disclosure provides a display panel, a method for driving the same and a display apparatus. The display panel includes a pixel circuit and a driving circuit. The pixel circuit includes at least one light emitting device; the light emitting device includes a multilayer quantum well structure; the driving circuit is to adjust a driving current that is input to the light emitting device, thereby enabling the light emitting device to emit light of a corresponding color that is varied with a size of the driving current.

### CROSS-REFERENCE TO RELATED APPLICATION

This application claims priority to Chinese Patent Application No. 201710896934.1 filed on Sep. 28, 2017, which is incorporated herein by reference in its entirety.

### TECHNICAL FIELD

The present disclosure relates to the field of display technology, and in particular to a display panel, a method for driving the same and a display apparatus.

### BACKGROUND

A full-color LED display is favored by the market because of its rich color, high saturation and high definition. But the full-color LED display in the related art is usually an integration of a plurality of single-color LEDs or is realized with short-wavelength LEDs in conjunction with fluorescence through secondary light emission. However, structures and process of full-color LEDs manufactured according to the above technical solutions for achieving the full-color LED display, are complex. Further, the above technical solutions for achieving the full-color LED display limits high pixels per inch (PPI) of the full-color LED display, and cannot satisfy high PPI requirements for display panels in the market.

Thus, how to reduce complexity of structures and process of the full-color LED display and realize high-PPI display is an urgent technical problem to be solved at present.

### SUMMARY

One embodiment of the present disclosure provides a display panel which includes a pixel circuit and a driving circuit. The pixel circuit includes at least one light emitting device; the light emitting device includes a multilayer quantum well structure; the driving circuit is to adjust a driving current that is input to the light emitting device, thereby enabling the light emitting device to emit light of a corresponding color that is varied with a size of the driving current.

Optionally, the light emitting device includes a GaN/InGaN multilayer quantum well structure.

Optionally, the pixel circuit further includes a first transistor, a storage capacitor, a second transistor, and a switch device that is configured to control a light-emitting time period of the light emitting device. A source terminal of the first transistor is configured to receive an external scan data signal; a drain terminal of the first transistor is coupled to a gate terminal of the second transistor; a source terminal of the second transistor is configured to receive an input voltage; a drain terminal of the second transistor is coupled to the light emitting device through the switch device; the switch device is configured to receive an external control signal that controls an on or off state of the switch device.

Optionally, the switch device includes a third thin film transistor; the first transistor and the third thin film transistor are NMOS transistors or PMOS transistors, and work in a triode region.

Optionally, the second transistor is a PMOS transistor and works in a saturated region.

Optionally, a turning-on time period of the switch device is determined by a pulse width of the external control signal.

One embodiment of the present disclosure provides a method for driving the above display panel which includes: turning on the first transistor by the external scan data signal and charging the storage capacitor; and, according to a display instruction, adjusting, by the driving circuit, a size of a driving current for driving the second transistor, thereby adjusting a size of a discharging current from the storage capacitor to the light emitting device; meanwhile, controlling, by the external control signal, turning on of the switch device and a turning-on time period of the switch device, thereby controlling a light-emitting time period of the light emitting device and a color of light emitted by the light emitting device.

Optionally, the method further includes keeping the second transistor turning on within at least one period of time after the first transistor is turned off by discharging the storage capacitor when the first transistor is turned off, thereby enabling the input voltage to output the current through the second transistor.

Optionally, light emitting intensities of the light emitting device is determined by a light-emitting time period of the light emitting device.

One embodiment of the present disclosure provides a display apparatus including the above display panel.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure.

FIG. 1 is a schematic diagram of a pixel circuit according to an exemplary embodiment of the present disclosure;

FIG. 2 is another schematic diagram of a pixel circuit according to an exemplary embodiment of the present disclosure;

FIG. 3 is a flow chart of a method for driving a display panel according to an exemplary embodiment of the present disclosure; and

FIG. 4 is a schematic diagram showing waveforms of a gate voltage of a first transistor, a scan data signal and a control signal according to an exemplary embodiment of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise indicated. The implementations set forth in the following description of exemplary embodiments do not represent all implementations consistent with the disclosure. Instead, they are merely examples of devices and methods consistent with aspects related to the disclosure as recited in the appended claims.

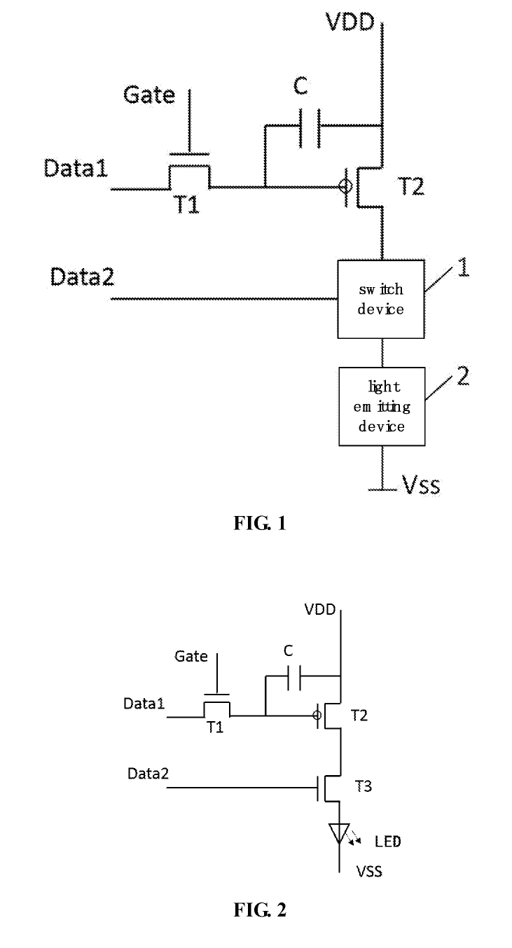

One embodiment of the present disclosure provides a display panel which includes a pixel driving circuit and a driving circuit. FIG. 1 is a schematic diagram of a pixel circuit according to an exemplary embodiment of the present disclosure. As shown in FIG. 1, the pixel circuit includes at least one light emitting device 2. The light emitting device 2 includes a multilayer quantum well structure. The driving circuit is used to adjust a driving current that is input to the light emitting device, thereby enabling the light emitting device to emit light of a corresponding color that is varied with sizes of the driving current.

The driving circuit can be implemented in a variety of circuit structures, which are not limited and are not shown. FIG. 1 shows an output voltage from the driving circuit. The output voltage from the driving circuit is equivalent to an input voltage V_{DD} of the pixel circuit. The driving circuit is used to adjust a driving current that is input to the light emitting device, thereby enabling the light emitting device to emit light of a corresponding color that is varied with sizes of the driving current.

As shown in FIG. 1, the pixel circuit further includes a first transistor, a storage capacitor, a second transistor, and a switch device 1 that is used to control a light-emitting time period of the light emitting device 2. A source terminal of the first transistor is used to receive an external scan data signal. A drain terminal of the first transistor is coupled to a gate terminal of the second transistor. A source terminal of the second transistor is used to receive a voltage V_{DD}. A drain terminal of the second transistor is coupled to the light emitting device 2 through the switch device 1. The switch device 1 is used to receive an external control signal that controls an on or off state of the switch device 1.

The driving circuit in the display panel provides the input voltage for the pixel circuit. The pixel circuit converts the input voltage into the driving current that drives the light emitting device to emit light. The light emitting device displays a variety of different colors under control if different input currents, thereby achieving the purpose of full-color displaying.

The light emitting device includes a multilayer quantum well structure which may be made of GaN/InGaN. In some embodiments, the light emitting device may be a GaN/InGaN multilayer quantum well structure LED. Specifically, the light emitting device includes an undoped GaN layer with a thickness of 2 um, a high-Si-doped N-type GaN layer, and an InGaN layer for improving quality. The light emitting device of this type may emit light having a wavelength of 460 nm-650 nm, thereby covering the entire visible spectrum. The wavelength of the emitted light is reduced from 650 nm to below 460 nm as the input current increases. Then, the color displayed by the light emitting device is determined by a current flowing though the light emitting device, and currents required for displaying red, green and blue colors are increased sequentially. For example, when the pixel circuit adopts a full-color LED with the GaN/InGaN multilayer quantum well structure, the LED displays the red color when the current is 15 mA; the LED displays the green color when the current is 200 mA; and the LED displays the blue color when the current is 400 mA.

When the light emitting device employs the LED with the GaN/InGaN multilayer quantum well structure, the light emitting device can display light of different colors based on different sizes of currents, thereby realizing that a single light emitting device can display a variety of different colors. When adopting the light emitting device of the above type, the color displayed by the light emitting device can be controlled by means of merely controlling the size of the driving current. Comparing with the method in the related art that a plurality of single-color LEDs are integrated to form a full-color display, the present disclosure can reduce space occupied by the light emitting device and power consumption.

FIG. 2 is a schematic diagram of a pixel circuit according to an exemplary embodiment of the present disclosure. A part of the pixel circuit except for the light emitting device is used to adjust and control sizes of the output current, and this part may employ a silicon-based complementary metal oxide semiconductor (CMOS) circuit. Since the transistor has the function of switching and signal modulation, the switch device 1 may employ a thin film transistor. To make a distinction, this thin film transistor is named as a third transistor. A gate terminal of the third transistor is used to receive an external control signal that can control an on or off state of the third transistor. A pulse width of the control signal determines a turning-on time period of the switch device 1. A source terminal of the third transistor is coupled to the drain terminal of the second transistor. A drain terminal of the third transistor is coupled to the light emitting device. The switch device can be implemented by means of the simple transistor, thus the switch device has a simple structure, occupies less hardware space and consumes less resource.

As shown in FIG. 1, the pixel circuit includes at least one light emitting device. FIG. 2 shows a situation that the pixel circuit includes a single light emitting device. Of course, the pixel circuit may also include a plurality of light emitting devices, and the purpose that a single light emitting device can display a variety of different colors may be realized in a similar way. The difference lies in that the single light emitting device and the plurality of light emitting devices are different in light emitting areas, light emitting intensities and displayed PPI. The single light emitting device has limited light emitting areas, and thus a plurality of light emitting devices may be formed on the silicon-based complementary metal oxide semiconductor (CMOS) circuit to realize full-color display with a large area and high PPI.

As shown in FIG. 2, the pixel circuit includes a first transistor T1, a storage capacitor C, a second transistor T2, and a light emitting device (i.e., LED), and a third transistor T3 that is used to control a light-emitting time period of the light emitting device. A source terminal of the first transistor T1 is used to receive an external scan data signal Data1. A drain terminal of the first transistor T1 is coupled to a gate terminal of the second transistor T2. A source terminal of the second transistor T2 is used to receive a voltage V_{DD}. A drain terminal of the second transistor T2 is coupled to the light emitting device through the third transistor T3. The third transistor T3 is used to receive an external control signal Data2 that controls an on or off state of the third transistor T3.

The first transistor T1 and the third transistor T3 are used as switch thin film transistors. The gate voltage of the first transistor T1 controls writing of the scan data signal Data1. When a voltage difference between a source voltage of the first transistor T1 and the gate voltage of the first transistor T1 enables the first transistor T1 to be turned on, the first transistor T1 is turned on, and then chargers the storage capacitor C coupled between the source terminal of the second transistor T2 and the gate terminal of the second transistor T2.

The scan data signal Data1 is written in through the first transistor T1, and is stored in the storage capacitor C. Meanwhile, a potential at the gate terminal of the second transistor T2 is increased as data is written in. when a voltage difference between a source voltage of the second transistor T2 and a gate voltage of the second transistor T2 enables the second transistor T2 to be turned on, the second transistor T2 is turned on, the input voltage V_{DD} outputs a current through the second transistor T2.

As can been from FIG. 2, if the third transistor T3 is not turned on, the current output by the input voltage V_{DD} through the second transistor T2 cannot flow through the light emitting device. When no current flows through the light emitting device, the light emitting device does not emit light. Thus, in fact, the third transistor T3 controls a time period in which the current flows through the light emitting device, i.e., a moment when the light emitting device emits light or when the light emitting device is turned off, and a light-emitting time period of the light emitting device.

The driving current can simultaneously drive several light emitting devices. When the light emitting devices are connected in series or in parallel, since the third transistor T3 is directly connected with the second transistor T2 and is located at a position for controlling the driving current to flow into the light emitting devices, the third transistor T3 can control on or off of one row/column of light emitting devices, thereby greatly reducing the number of the switch devices 1, facilitating miniaturization of the display panel and avoiding waste of resources and delay caused by many control switches.

The first transistor T1 and the third transistor T3 are NMOS transistors or PMOS transistors, and work in a triode region.

One transistor has switching characteristics when working in the triode region. The first transistor T1 and the third transistor T3 work in the triode region and belong to gate control components. When the voltage difference between voltages of the gate terminal and the source terminal of the first transistor T1 reaches a threshold voltage, the first transistor T1 is turned on. The third transistor T3 works in a similar way which is not elaborated herein.

The second transistor T2 is used as a driver thin film transistor. When the first transistor T1 is turned on, the storage capacitor C is charged. When the voltage difference between voltages of the gate terminal and the source terminal of the second transistor T2 is greater than a threshold voltage, the second transistor T2 is turned on, and then the input voltage V_{DD} outputs a current through the second transistor T2. When the first transistor T1 is turned off, the storage capacitor C discharges. Thus, after the first transistor T1 is turned off, within at least one period of time, the second transistor T2 is still turned on, and the input voltage V_{DD} still outputs the current through the second transistor T2.

When the gate voltage of the second transistor T2 is less than the source voltage of the second transistor T2, the second transistor T2 is turned off, and then the input voltage V_{DD} cannot output the current through the second transistor T2.

The second transistor T2 is a PMOS transistor and works in a saturated region. During the process of charging the storage capacitor C, the potential at the gate terminal of the second transistor T2 is increased accordingly. When the second transistor T2 works in the saturated region and the voltage difference between voltages of the gate terminal and the source terminal of the second transistor T2 is continuously increased, the current flowing through the second transistor T2 may be calculated through the following formula:

I=½μ(W/L)(V_{gs}−Vₜₕ)²

As can be seen from the above formula, the size of the current output by the input voltage V_{DD} through the second transistor T2 is determined by the voltage difference between the voltages of the gate terminal and the source terminal of the second transistor T2. As can be seen from the relationship between the size of the current and the color displayed by the light emitting device, in the process that the voltage difference between the voltages of the gate terminal and the source terminal of the second transistor T2 is gradually increased, when the third transistor T3 is turned on at the same time, the color displayed by the LED is changed in sequence of red, green and blue.

The size of the current flowing through the light emitting device is affected by the signal intensity of the scan data signal Data1. The signal intensity of the scan data signal Data1 may be set according to actual needs.

When the light emitting device employs the GaN/InGaN multilayer quantum well structure LED, the size of the current flowing through the LED determines the color displayed by the LED. The first transistor T1, the second transistor T2 and the storage capacitor C are used to adjust and control the size of the current flowing through the light emitting device, in essence, they adjust and control the color displayed by the light emitting device.

The third transistor T3 and the first transistor T1 are used as switch thin film transistors. When an external voltage applied to the gate terminal of the third transistor T3 reaches the threshold voltage, the third transistor T3 is turned on. At this point, when the input voltage V_{DD} outputs a current through the second transistor T2, the output current flows towards the light emitting device through the third transistor T3, thereby lightening the light emitting device.

The third transistor T3 is used to control on or off the light emitting device. The longer the light-emitting time period of the light emitting device is, the greater the brightness of the LED is. The third transistor T3, in fact, controls the light emitting intensities of the light emitting device.

Correspondingly, one embodiment of the present disclosure further provides a method for driving the above display panel. FIG. 3 is a flow chart of the method for driving the display panel. As shown in FIG. 3, the method includes the following steps S30 and S31.

The step S30 is to turn on the first transistor by an external scan data signal and charge the storage capacitor.

The source terminal of the first transistor receive the external scan data signal, and the first transistor is turned on when the voltage difference between voltages of the gate terminal and the source terminal of the first transistor T1 reaches the threshold voltage. The scan data signal, i.e. the signal represented by Data1 in FIG. 1, is input to the storage capacitor coupled to the drain terminal of the first transistor, through the first transistor that is turned on. In the charging process, a potential of the capacitor gradually rises. Since the drain terminal of the first transistor is also coupled to the gate terminal of the second transistor, the potential at the gate terminal of the second transistor rises accordingly, thereby preparing for turning on the second transistor.

The step S31 is to, according to a display instruction, adjust, by the driving circuit, a size of a driving current for driving the second transistor, thereby adjusting a size of a discharging current from the storage capacitor to the light emitting device; meanwhile, control, by an external control signal, turning on of the switch device and a turning-on time period of the switch device, thereby controlling a light-emitting time period of the light emitting device and a color of emitted light.

The display instruction is a display instruction set according to requirements for the light emitting device. The display instruction includes: a color displayed by each light emitting device, a moment for displaying the color, a time length for displaying the color, brightness, etc., for example, a color displayed by each pixel unit and a time length for displaying this color obtained by decomposing a video clip. According to the display instruction, the driving circuit dynamically adjusts the input voltage V_{DD} to the pixel circuit, thereby adjusting the size of the driving current for driving the second transistor.

When receiving an external scan data signal and turning on the first transistor under control the gate voltage of the first transistor, the storage capacitor coupled between the source terminal and the gate terminal of the second transistor is charged. When a potential difference between a gate potential of the second transistor and a source potential of the second transistor is greater than a threshold voltage, the second transistor is turned on, and the input voltage V_{DD} outputs a current through the second transistor.

When the second transistor is turned on, the relationship between the output current and the potential difference between the gate potential of the second transistor and the source potential of the second transistor is shown by the following formula:

I=½μ(W/L)(V_{gs}−Vₜₕ)²

When the first transistor is turned off, the storage capacitor discharges. After the first transistor is turned off, within at least one period of time, the second transistor is still turned on, and the input voltage V_{DD} still outputs the current through the second transistor. When the gate voltage of the second transistor is less than the source voltage of the second transistor, the second transistor is turned off, and then the input voltage V_{DD} cannot output the current through the second transistor.

As can be seen from the above analysis, the current output from the second transistor is controlled by the first transistor and the second transistor. The first transistor is used to control writing of control data and control turning on of the second transistor. The potential difference between the gate potential of the second transistor and the source potential of the second transistor determines the size of the output current, i.e., determining the color displayed by the light emitting device coupled to the driving circuit. In this way, Realization of the color displayed by the light emitting device can be controlled with few components, thereby simplifying the structure and avoiding unnecessary waste of system resources.

The turning-on time period of the third transistor is not related to whether first transistor or the second transistor is turned on. Thus, there is no obvious succession between using the external control signal to control the turning-on time period of the switch device, and turning-on time periods of the first transistor and the second transistor.

The process of using the external control signal to control turning on and the turning-on time period of the switch device is described as follow.

In one embodiment of the present disclosure, the switch device 1 may be a thin film transistor that works in a triode region, i.e., the third transistor. The third transistor and the first transistor are used as switch transistors and they are turned on in a similar way. When the gate voltage of the third transistor, controlled by the external control signal Data2, enables the voltage difference between the gate voltage of the third transistor and the source voltage of the third transistor to reach the threshold voltage, the third transistor is turned on. Similarly, the turning-on time period of the third transistor is determined by a pulse width of the control signal Data2. At this point, when the input voltage V_{DD} outputs a current through the second transistor, the output current flows towards the light emitting device 2 through the third transistor, thereby lightening the light emitting device 2.

When the third transistor T3 is turned off, no matter whether the input voltage V_{DD} outputs a current through the second transistor T2 at this point, the output current cannot lighten the light emitting device 2.

Turning on or off of the third transistor T3 determines a light-emitting moment and a light-emitting time length for the light emitting device. A time length for displaying light of each of different colors including red, green and blue, is controlled by the output current controlled by the first transistor T1 and the second transistor T2 when the third transistor T3 is turned on.

The third transistor T3 is used to control on or off of the light emitting device. The longer the light-emitting time period of the light emitting device is, the greater the brightness of the LED is. The third transistor T3, in fact, controls the light emitting intensities of the light emitting device.

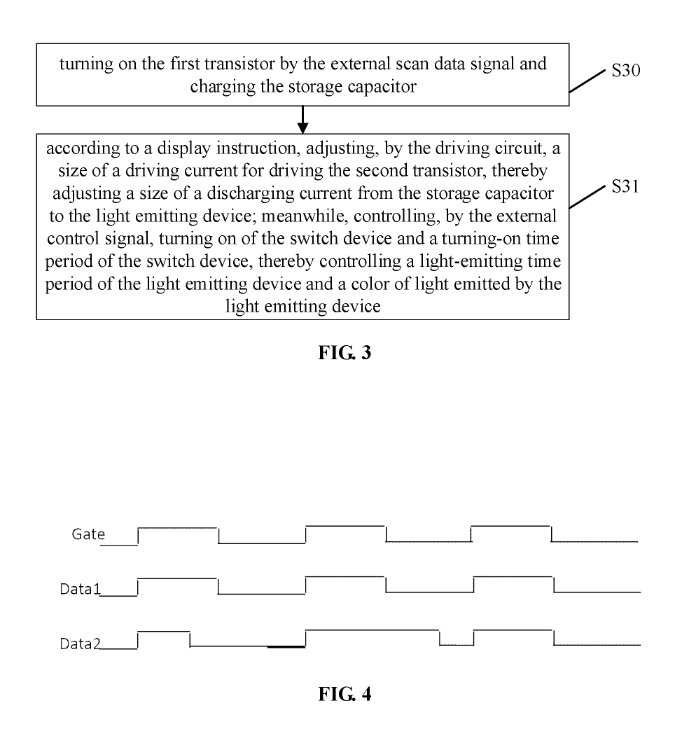

FIG. 4 is a schematic diagram showing waveforms of a gate voltage of a first transistor, a scan data signal Data1 and a control signal Data2 according to an exemplary embodiment of the present disclosure. The gate voltage of the first transistor determines a writing time of the scan data signal Data1. When the first transistor is turned on, the scan data signal Data1 is storage in the storage capacitor C. the second transistor and the storage capacitor cooperate to adjust the driving current for the light emitting device. A pulse width of the control signal Data2 determines a moment when to turn on or off the third transistor and the turning-on time period of the third transistor. The longer the turning-on time period of the third transistor is, the greater the brightness of the light emitting device is.

Correspondingly, one embodiment of the present disclosure further provides a display apparatus which includes the above display panel. The display apparatus may be any product or component that has displaying function, such as an electronic paper, an OLED panel, a mobile phone, a tablet computer, a television, a monitor, a notebook computer, a digital photo frame, a navigator.

Since the display apparatus includes the above display panel, the display apparatus has all advantages of the above display panel.

In sum, in the display panel provided in some embodiments of the present disclosure, the driving circuit provides the current to drive the light emitting device to display colors; the first transistor and the second transistor in the pixel circuit control the color displayed by the light emitting device; the switch device controls the light-emitting time period and the light emitting intensities of the light emitting device; thus, the pixel circuit uses three transistors and one storage capacitor to provide different driving currents for the light emitting device, thereby controlling the light emitting device to display different colors. The structure is simple and easy to implement. Each pixel circuit includes at least one light emitting device capable of displaying different colors, thereby achieving displaying with high PPI and enhancing the displaying performance of the display apparatus.

The above are merely the preferred embodiments of the present disclosure and shall not be used to limit the scope of the present disclosure. It should be noted that, a person skilled in the art may make improvements and modifications without departing from the principle of the present disclosure, and these improvements and modifications shall also fall within the scope of the present disclosure.

What is claimed is:

1. A display panel comprising:
a pixel circuit; and
a driving circuit;
wherein the pixel circuit includes at least one light emitting device; the light emitting device includes a multilayer quantum well structure; and the driving circuit is configured to adjust a driving current that is input to the light emitting device, thereby enabling the light emitting device to emit light of a corresponding color that is varied with a size of the driving current.

2. The display panel of claim 1, wherein the light emitting device includes a GaN/InGaN multilayer quantum well structure.

3. The display panel of claim 1, wherein the pixel circuit further includes a first transistor, a storage capacitor, a second transistor, and a switch device that is configured to control a light-emitting time period of the light emitting device; and
wherein a source terminal of the first transistor is configured to receive an external scan data signal; a drain terminal of the first transistor is coupled to a gate terminal of the second transistor; a source terminal of the second transistor is configured to receive an input voltage; a drain terminal of the second transistor is coupled to the light emitting device through the switch device; and the switch device is configured to receive an external control signal that controls an on or off state of the switch device.

4. The display panel of claim 3, wherein the switch device includes a third thin film transistor; the first transistor and the third thin film transistor are NMOS transistors or PMOS transistors, and work in a triode region.

5. The display panel of claim 3, wherein the second transistor is a PMOS transistor and works in a saturated region.

6. The display panel of claim 3, wherein a turning-on time period of the switch device is determined by a pulse width of the external control signal.

7. A method for driving the display panel of claim 3, comprising:
turning on the first transistor by the external scan data signal and charging the storage capacitor; and
according to a display instruction, adjusting, by the driving circuit, a size of a driving current for driving the second transistor, thereby adjusting a size of a discharging current from the storage capacitor to the light emitting device; meanwhile, controlling, by the external control signal, turning on of the switch device and a turning-on time period of the switch device, thereby controlling a light-emitting time period of the light emitting device and a color of light emitted by the light emitting device.

8. The method of claim 7, further comprising:
keeping the second transistor turning on within at least one period of time after the first transistor is turned off by discharging the storage capacitor when the first transistor is turned off, thereby enabling the input voltage to output the current through the second transistor.

9. The method of claim 7, wherein light emitting intensities of the light emitting device is determined by a light-emitting time period of the light emitting device.

10. A display apparatus comprising a display panel;
wherein the display panel includes:
a pixel circuit; and
a driving circuit;
wherein the pixel circuit includes at least one light emitting device; the light emitting device includes a multilayer quantum well structure; and the driving circuit is configured to adjust a driving current that is input to the light emitting device, thereby enabling the light emitting device to emit light of a corresponding color that is varied with a size of the driving current.

11. The display apparatus of claim 10, wherein the light emitting device includes a GaN/InGaN multilayer quantum well structure.

12. The display apparatus of claim 10, wherein the pixel circuit further includes a first transistor, a storage capacitor, a second transistor, and a switch device that is configured to control a light-emitting time period of the light emitting device; and
wherein a source terminal of the first transistor is configured to receive an external scan data signal; a drain terminal of the first transistor is coupled to a gate terminal of the second transistor; a source terminal of the second transistor is configured to receive an input voltage; a drain terminal of the second transistor is coupled to the light emitting device through the switch device; and the switch device is configured to receive an external control signal that controls an on or off state of the switch device.

13. The display apparatus of claim 12, wherein the switch device includes a third thin film transistor; the first transistor and the third thin film transistor are NMOS transistors or PMOS transistors, and work in a triode region.

14. The display apparatus of claim 12, wherein the second transistor is a PMOS transistor and works in a saturated region.

15. The display apparatus of claim 12, wherein a turning-on time period of the switch device is determined by a pulse width of the external control signal.
